(19) United States
(12) Patent Application Publication
(10) Pub. No.: US 2025/0221082 A1
(43) Pub. Date: Jul. 3, 2025

(54) LIGHT-EMITTING COMPONENT

(71) Applicant: ams-OSRAM International GmbH, Regensburg (DE)

(72) Inventor: Wim HERTOG, Regensburg (DE)

(21) Appl. No.: 18/850,974

(22) PCT Filed: Jan. 16, 2023
(86) PCT No.: PCT/EP2023/050830

§ 371 Date: Sep. 25, 2024

(30) Foreign Application Priority Data
Mar. 25, 2022 (DE) 10 2022 202 973.9

(51) Int. Cl. H10F 55/00; H01L 25/16; H10F 77/40; H10F 77/45

(52) U.S. Cl. CPC H10F 55/18; H01L 25/167; H10F 77/413; H10F 77/45

(57) ABSTRACT

The invention relates to a light-emitting component. The light-emitting component comprises an emitter group of light-emitting semiconductor chips configured to generate different light radiations and an electronic semiconductor chip for driving the light-emitting semiconductor chips. The light-emitting semiconductor chips are arranged on the electronic semiconductor chip. The electronic semiconductor chip comprises a plurality of integrated photodiodes. Each light-emitting semiconductor chip of the emitter group is associated with at least one photodiode of the electronic semiconductor chip in order to detect the light radiation generated by the respective light-emitting semiconductor chip.

The present invention relates to a light-emitting component. The light-emitting component comprises an emitter group of light-emitting semiconductor chips configured to generate different light radiations and an electronic semiconductor chip for driving the light-emitting semiconductor chips.

This patent application claims priority to German patent application 102022202973.9, the disclosure of which is hereby incorporated by reference.

Multicolor light-emitting components which may be employed e.g. in the automotive field or in the field of video wall applications may be realized in various ways. The components may comprise a plurality of light-emitting semiconductor chips configured to generate different colored light radiations. By appropriately driving the light-emitting semiconductor chips, a total light radiation with a predetermined chromaticity may be generated and the chromaticity may be tuned in a desired manner. Such color-tunable components may furthermore be embodied as intelligent lighting components in that the components additionally comprise an in-package electronic semiconductor chip for driving the light-emitting semiconductor chips. The electronic semiconductor chip may act as a current source for each color channel and handle communication with an external main controller.

The light-emitting semiconductor chips and the related multicolor light-emitting components may undergo changes in the light radiation generated depending on the lifetime and parameters such as variations in temperature and driving current. Depending on the application, however, a high color stability over time and high color homogeneity may be re-quired. To address this problem, (semi-) passive compensation mechanisms may be applied which aim at preventing (e.g. by selecting stable epitaxial recipes) or predicting mechanisms causing color point instability. With regard to the latter, characteristics of emitter behavior in function of driving current, temperature and operating time may be used to provide color-compensation look-up tables that may be combined with temperature sensors to predict the optical behavior. This procedure may, however, be affected with inaccuracies. It is also possible to apply external optical sensors (e.g. spectrally resolving) in combination with respective optics such that the radiation changes may be measured directly. This approach, however, may involve high complexity and costs. Moreover, usually only a plurality of light-emitting components may be jointly monitored with an external sensor, thus obtaining only averaged data of multiple components.

The object of the present invention is to specify a solution for an improved light-emitting component.

This object is achieved by a light-emitting component according to independent claim 1. Further advantageous embodiments of the invention are specified in the dependent claims.

According to one aspect of the invention, a light-emitting component is proposed. The light-emitting component comprises an emitter group of light-emitting semiconductor chips configured to generate different light radiations and an electronic semiconductor chip for driving the light-emitting semiconductor chips. The light-emitting semiconductor chips are arranged on the electronic semiconductor chip. The electronic semiconductor chip comprises a plurality of integrated photodiodes. Each light-emitting semiconductor chip of the emitter group is associated with at least one photodiode of the electronic semiconductor chip in order to detect the light radiation generated by the respective light-emitting semiconductor chip.

The proposed light-emitting component makes it possible to provide an in-component optical feedback system. During operation of the light-emitting component, the light radiations generated by the light-emitting semiconductor chips of the emitter group may be reliably detected by means of the integrated photodiodes of the electronic semiconductor chip that are assigned to these light-emitting semiconductor chips. In this way, potential changes and deviations in the generated light radiations that may be due to effects such as driving current variations, temperature fluctuations, aging time and degradation may be directly and individually measured for each of the monitored light-emitting semiconductor chips. Based on the detected light radiations or respective measurement signals generated by the photodiodes, the driving of the light-emitting semiconductor chips may be adapted such that the observed changes and deviations in the light radiations or related changes and deviations in a total light radiation generated by the light-emitting component may be counteracted and therefore compensated. Consequently, it is possible to operate the light-emitting component in such a way that, despite the influencing effects, a total light radiation with a predetermined characteristic or chromaticity may be generated and tuned in a desired, accurate and reliable manner. The light-emitting component may thus feature a high colorimetric stability and color point accuracy. This may apply for the full lifetime of the component.

The usage of the in-component electronic semiconductor chip with the integrated photodiodes in this context allows the radiation measurements to be carried out in a simple and cost-effective manner. This applies in comparison to employing an external optical sensor which, if applicable, may be combined with a complicated optical system to guide the light radiation to such a sensor.

Moreover, with regard to lighting applications in which a plurality of the proposed light-emitting components is employed, radiation measurements may be carried out individually with the photodiodes of the respective electronic semiconductor chips, and thus an active individual correction and compensation of changes and deviations in the light radiation produced may be performed with respect to each of the light-emitting components. Such a procedure is more accurate and reliable than a compensation method carried out on the basis of averaged behavioral data of multiple components obtained by using an external optical sensor assigned to these multiple components.

In the following, further possible details and embodiments are described which may be considered for the light-emitting component.

The light-emitting semiconductor chips of the emitter group, which may also be referred to as emitters, are configured to generate different, i.e. different colored light radiations. By appropriately driving the light-emitting semiconductor chips, a total or mixed light radiation may be generated by the light-emitting component with a predetermined color or chromaticity. The chromaticity of the light radiation may i.a. depend on the relative intensities of the individual light radiations generated by the light-emitting semiconductor chips. Consequently, tuning or changing the chromaticity of the total light radiation may be effected by tuning or changing the intensities of the light radiations generated by the individual light-emitting semiconductor chips. As already described above, the compensation of unintended changes and deviations in the light radiations generated by the light-emitting semiconductor chips which are caused by influencing effects makes it possible to reliably operate the light-emitting component as to emit a total light radiation with a desired chromaticity.

The light-emitting semiconductor chips may be arranged or mounted on a front side of the electronic semiconductor chip, and may be mechanically and electrically connected to the electronic semiconductor chip in an appropriate manner. With regard to this, both the light-emitting semiconductor chips and the electronic semiconductor chip may comprise respective contacts that are connected to each other. For the purpose of connecting the light-emitting semiconductor chips and the electronic semiconductor chip and their contacts, connection materials or structures such as a solder material, an adhesive or bond wires may be utilized. The integrated photodiodes of the electronic semiconductor chip may be formed in a region of the front side of the same.

The electronic semiconductor chip, which may also be referred to as IC (integrated circuit), driver IC or driver chip, is configured to electrically drive or individually electrically drive the light-emitting semiconductor chips such that the light-emitting semiconductor chips generate a light radiation. The electronic semiconductor chip may thereby act as a current source for each light-emitting semiconductor chip and therefore color channel. The electronic semiconductor chip may also be configured to process measurement signals produced by the integrated photodiodes that may be generated by the photodiodes upon being irradiated by the associated light-emitting semiconductor chips. The processing may comprise evaluating and/or digitalizing the measurement signals. With regard to the aforementioned functions, the electronic semiconductor chip may comprise respective circuit structures connected to the light-emitting semiconductor chips and to the photodiodes.

The driving of the light-emitting semiconductor chips by the electronic semiconductor chip may be carried out on the basis of a PWM (pulse width modulation) control scheme. In this regard, the light-emitting semiconductor chips may be periodi-cally operated by means of the electronic semiconductor chip. To this end, the light-emitting semiconductor chips may be powered with a current or nominal current for certain times and remain off in between such times. The ratio of durations of the on and off times and thus the duty cycle defines the perceivable average intensity and brightness of a light radiation generated by a light-emitting semiconductor chip. Therefore, the intensities of light radiations generated by the light-emitting semiconductor chips may be set and changed by the electronic semiconductor chip individually setting and changing the respective duty cycles.

It is also possible, if applicable, to provide a current control scheme as an alternative or in addition. With regard to this, the electronic semiconductor chip may be configured to individually set and change the current or nominal current applied to the light-emitting semiconductor chips. In this way, the color point of a light radiation generated by a light-emitting semiconductor chip may be set and changed.

The aforementioned processing of photodiode signals by the electronic semiconductor chip may include evaluating the same. In this sense, according to a further embodiment, it is provided that the electronic semiconductor chip is configured to drive the light-emitting semiconductor chips in response to the light radiation detected by the photodiodes associated with the light-emitting semiconductor chips. The electronic semiconductor chip may thereby evaluate or analyze the measurement signals provided by the integrated photodiodes and, based on this, control or adjust the driving of the light-emitting semiconductor chips. In this regard, in the event that a change or deviation in the light radiation generated by at least one light-emitting semiconductor chip is detected by the electronic semiconductor chip on the basis of the corresponding photodiode signals, the electronic semiconductor chip may adapt the driving of at least one light-emitting semiconductor chip to compensate for the change or deviation. By means of this procedure, an in-component and therefore simple and fast correction or compensation of undesired changes and deviations occurring in the light radiations generated by the light-emitting semiconductor chips may be realized.

The lighting operation of the light-emitting component may be controlled by an external main controller. With regard to this, the electronic semiconductor chip of the light-emitting component may handle a respective communication with such a main controller. This may include receiving command signals from the main controller based on which the electronic semiconductor chip of the light-emitting component may carry out the driving of the light-emitting semiconductor chips. The command signals may specify parameters of the total light radiation to be emitted by the light-emitting component such as an intensity specification and a specification related to a color or chromaticity.

The light-emitting semiconductor chips of the light-emitting component that are arranged or mounted on the electronic semiconductor chip may be LED (light-emitting diode) chips. The light-emitting semiconductor chips may comprise a semiconductor layer sequence with an active zone for light radiation generation.

The light-emitting component is configured such that the photodiodes of the electronic semiconductor chip assigned to the light-emitting semiconductor chips may be irradiated with the light radiations generated by the latter during operation. The configuration may be such that the respective photodiodes may be irradiated only or substantially only by the associated light-emitting semiconductor chips. In this context, the following embodiments may be implemented.

In a further embodiment, the light-emitting semiconductor chips of the light-emitting component are volume-emitting semiconductor chips. In this embodiment, the light-emitting semiconductor chips are configured to emit the generated light radiation at least via a front side and lateral sides of the semiconductor chips. This allows the irradiation of integrated photodiodes of the electronic semiconductor chip with light radiations generated by the associated light-emitting semiconductor chips to be realized in a simple and reliable manner. The volume-emitting semiconductor chips, which may be also referred to as volume emitters, may comprise, apart from the aforementioned semiconductor layer sequence, a transmissive chip substrate such as a sapphire substrate.

With regard to the aforementioned sides, the light-emitting semiconductor chips may comprise a back side opposite to the front side via which the light-emitting semiconductor chips may be mounted on the electronic semiconductor chip. The lateral sides of the light-emitting semiconductor chips may extend between and connect the back and front side. The emission of light radiation may also take place, if applicable, via the back side of the light-emitting semiconductor chips.

In a further embodiment, the light-emitting component further comprises a reflective layer comprising reflective particles arranged on the electronic semiconductor chip in regions laterally to and between the light-emitting semiconductor chips. The reflective layer, which may be configured as a reflective casting compound, may comprise a transmissive basic material such as silicone in which the reflective particles are embedded or distributed. The reflective particles may be titanium dioxide (TiO₂) particles. The reflective layer may directly adjoin the electronic semiconductor chip or a front side of the same and may directly adjoin the light-emitting semiconductor chips or lateral sides of the same. The reflective layer may comprise such a thickness that the reflective layer extends to the front sides of the light-emitting semiconductor chips, wherein the front sides of the same are not covered by the reflective layer. Alternatively, a smaller layer thickness may be present such that the light-emitting semiconductor chips may protrude from the reflective layer.

In the aforementioned embodiment, the reflective particles may serve to reflect and scatter a light radiation. This may e.g. apply to ambient light to which the light-emitting component may be exposed. In this regard, the reflective layer covering the electronic semiconductor chip in regions laterally to and between the light-emitting semiconductor chips may block and therefore prevent or substantially suppress the ambient light radiation from reaching the integrated photodiodes of the electronic semiconductor chip associated with the light-emitting semiconductor chips with the result that the ambient light radiation may not or may only be insignificantly noticeable in the measurement signals produced by these photodiodes. The reflective layer may furthermore reliably ensure that the light radiations generated by the light-emitting semiconductor chips reach the associated photodiodes, whereas the irradiation of photodiodes by light-emitting semiconductor chips that are not associated with these photodiodes is prevented or substantially suppressed. This enables the photodiode signals to originate solely or substantially from the light radiations generated by the associated light-emitting semiconductor chips. As a result, a high signal-to-noise ratio may be achieved.

With regard to the aforementioned irradiation function of the reflective layer, according to a further embodiment it is provided that the photodiodes associated with the light-emitting semiconductor chips are located in regions laterally to the respective light-emitting semiconductor chips such that these photodiodes may be irradiated with the light radiation generated by the respective light-emitting semiconductor chips via the reflective layer. In this embodiment, the light radiations generated by the light-emitting semiconductor chips may be emitted via the lateral sides of the same and thereby coupled into the reflective layer adjoining the lateral sides. This, and additionally due to the reflecting or scattering property of the reflective particles, allows the reflective layer to be illuminated with the light radiations in regions close to and laterally surrounding the respective light-emitting semiconductor chips, wherein the light radiations may propagate from the emitters through the reflective layer to the associated photodiodes. In combination with an appropriate location of the photodiodes in regions laterally to the associated light-emitting semiconductor chips, it may be achieved that the irradiation of photodiodes with light radiations generated by light-emitting semiconductor chips that are not assigned to these photodiodes is prevented or substantially suppressed.

In a further embodiment, the photodiodes associated with the light-emitting semiconductor chips are located underneath the respective light-emitting semiconductor chips such that these photodiodes may be irradiated with the light radiation generated by the respective light-emitting semiconductor chips via a back side of the respective light-emitting semiconductor chips. In this embodiment, the irradiation of integrated photodiodes of the electronic semiconductor chip with light radiations generated by the associated light-emitting semiconductor chips may be effected in a direct manner, thus enabling a high signal-to-noise ratio. In this embodiment, the irradiation of the respective photodiodes may be achieved without the aforementioned reflective layer, whereby such a layer may be omitted, if applicable. This minimalistic approach enables a cost saving.

The light-emitting component may be a multicolor light-emitting component such as an RGB (red, green, blue) component. In this sense, according to a further embodiment, it is provided that the emitter group comprises a red-emitting semiconductor chip configured to generate a red light radiation, a green-emitting semiconductor chip configured to generate a green light radiation and a blue-emitting semiconductor chip configured to generate a blue light radiation. By respectively driving the different light-emitting semiconductor chips, a total light radiation with a desired color from a wide range of colors (including white) may be emitted by the light-emitting component. The red light radiation may be related to a wavelength range from 610 nm to 700 nm. The green light radiation may be related to a wavelength range from 510 nm to 570 nm. The blue light radiation may be related to a wavelength range from 430 nm to 480 nm.

The photodiodes of the electronic semiconductor chip may correspond to each other in their layout, and may comprise respective diode structures such as a p-n junction, which may be realized by inversely doped semiconductor layer regions of the electronic semiconductor chip. The electronic semiconductor chip may be based on silicon as a semiconductor material such that the photodiodes may be silicon photodiodes.

The light-emitting component may be configured such that only unfiltered or clear photodiodes are employed with the electronic semiconductor chip, thereby omitting the provision of optical filters assigned to the photodiodes. This allows the light-emitting component to be implemented in a cost-effective manner. With the use of unfiltered photodiodes, changes and deviations in the intensity of the light radiations generated by the associated light-emitting semiconductor chips may be detected. Such changes and deviations may be due to effects such as temperature variations and semiconductor degradation due to operating time.

Alternatively, the use of optical filters may be considered with respect to a part of the integrated photodiodes. In this regard, according to a further embodiment, at least one of the light-emitting semiconductor chips is associated with a photodiode group of photodiodes of the electronic semiconductor chip in order to detect the light radiation generated by that light-emitting semiconductor chip, and the electronic semiconductor chip comprises, for each of the integrated photodiodes of the photodiode group, an upstream filter with an individual filter characteristic that is different from the filter characteristics of the respective other filters. In this way, a filtering of the light radiation may be effected before it reaches the photodiodes of the photodiode group.

The aforementioned embodiment makes it possible, by respectively evaluating the measurement signals produced by the photodiodes of the photodiode group upon being irradiated with the respective filtered light radiation, to detect, in addition to a change or deviation in intensity, a change in color point or chromaticity of the light radiation generated by the associated light-emitting semiconductor chip. This is because a change in color point or chromaticity is accompanied by a shift of the spectral intensity distribution of the light radiation which may be reflected by the measurement signals provided by the filtered photodiodes. For this purpose, the applied filters or their filter characteristics are matched to the spectral behavior of the respective light-emitting semiconductor chip. The change in color or chromaticity may be due to a temperature change, change in driving parameters such as forward current or semiconductor degradation.

The upstream filters may be bandpass filters, and may be realized in the form of filter layers of the electronic semiconductor chip that are arranged on the associated photodiodes of the photodiode group. The filter layers may e.g. be dielectric layers.

In a further embodiment, the light-emitting semiconductor chip associated with the filtered photodiode group is a red-emitting semiconductor chip configured to generate a red light radiation. With such a semiconductor chip, the behavior described above may occur in that effects such as temperature fluctuations and aging time may result in a change or significant change in chromaticity of the generated light radiation.

In a further embodiment, the electronic semiconductor chip or the plurality of integrated photodiodes of the same comprise at least one photodiode provided to detect an ambient light radiation. In this embodiment, it may be taken into account that the other photodiodes of the electronic semiconductor chip that are assigned to the light-emitting semiconductor chips and provided to detect the light radiations generated by the latter may also be irradiated by the ambient light radiation to some extent such that the ambient light radiation may be noticeable to some degree in the measurement signals produced by these photodiodes. Consequently, by means of a photodiode provided to detect the ambient light radiation and on the basis of measurement signals produced by this photodiode, it is possible to capture the influence of the ambient light radiation and to factor it out when evaluating the measurement signals produced by the other photodiodes. As a result, an improved signal-to-noise ratio may be provided.

As described above, the light-emitting component may comprise a reflective layer covering the electronic semiconductor chip in regions laterally to and between the light-emitting semiconductor chips. In this way, the integrated photodiodes of the electronic semiconductor chip that are associated with the light-emitting semiconductor chips may be covered by the reflective layer, as well. The light-emitting component may be further configured such that the at least one photodiode provided to detect the ambient light radiation is not covered by the reflective layer.

Apart from the above-described components, the light-emitting component may comprise further components. As an example, the light-emitting component may comprise a base carrier on which the electronic semiconductor chip is arranged. The base carrier may be or may comprise e.g. a metallic lead frame, a ce-ramic carrier or a PCB (printed circuit board). A further potential component is a transmissive or clear cover layer. The cover layer may be e.g. a silicone layer, and may be arranged on the light-emitting semiconductor chips and on the reflective layer, if present.

As described above, an external main controller may be employed to control the operation of the light-emitting component, and the main controller may provide and communicate command signals to the light-emitting component for this purpose. In this respect, it may also be considered that the electronic semiconductor chip of the light-emitting component, instead of evaluating the photodiode signals produced by the integrated photodiodes, is configured to communicate such signals, if applicable in processed form such as in the form of digital signals, to the main controller, whereupon the main controller may evaluate these signals and provide respective command signals based on them.

The light-emitting component may be applied in different technical fields. Examples include transmissive or emissive displays, interior or exterior automotive illumination, show or stage illumination and indoor or outdoor general lighting. With regard to such lighting applications, a plurality of light-emitting components may be applied and operated in a combined manner, and may be controlled by an external main controller.

The advantageous configurations and developments of the invention explained above and/or presented in the dependent claims may—apart from, for example, in cases of clear dependencies or incompatible alternatives—be employed individually or else in any desired combination with one another.

The above-described properties, features and advantages of this invention and the way in which they are achieved will become clearer and more clearly understood in association with the following description of exemplary embodiments which are explained in greater detail in association with the schematic drawings, in which:

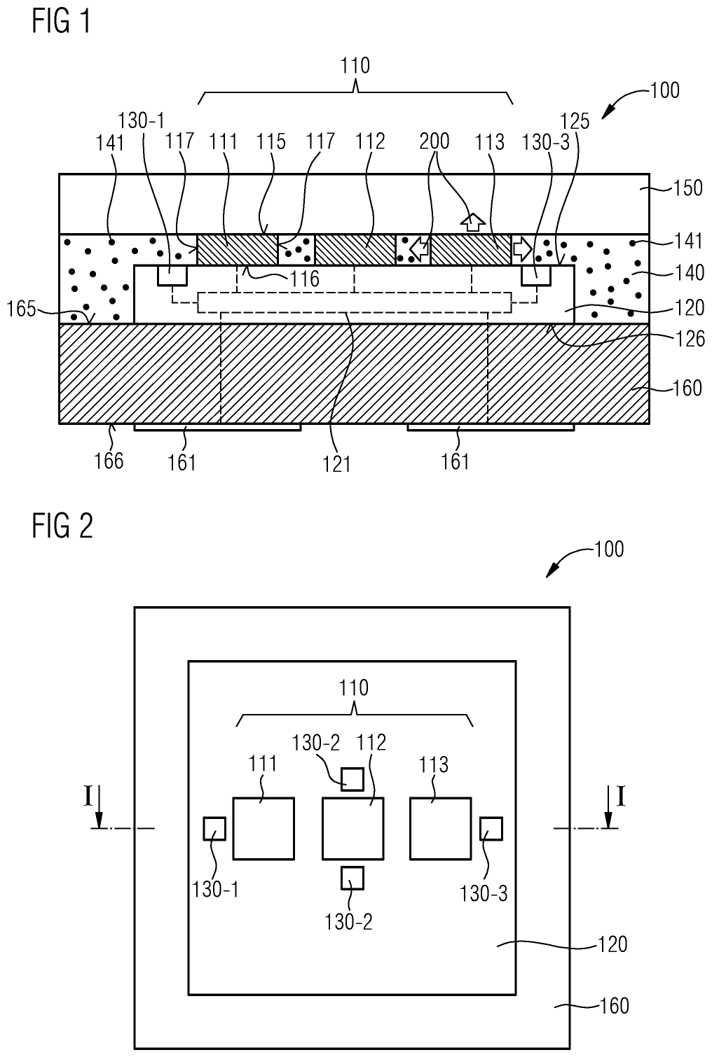

FIGS. 1 and 2 show a lateral sectional illustration and a plan view illustration of a light-emitting component comprisesing a plurality of emitters and a driver chip, wherein the driver chip comprises integrated photodiodes located in regions laterally to the emitters and provided to detect light radiations generated by the emitters;

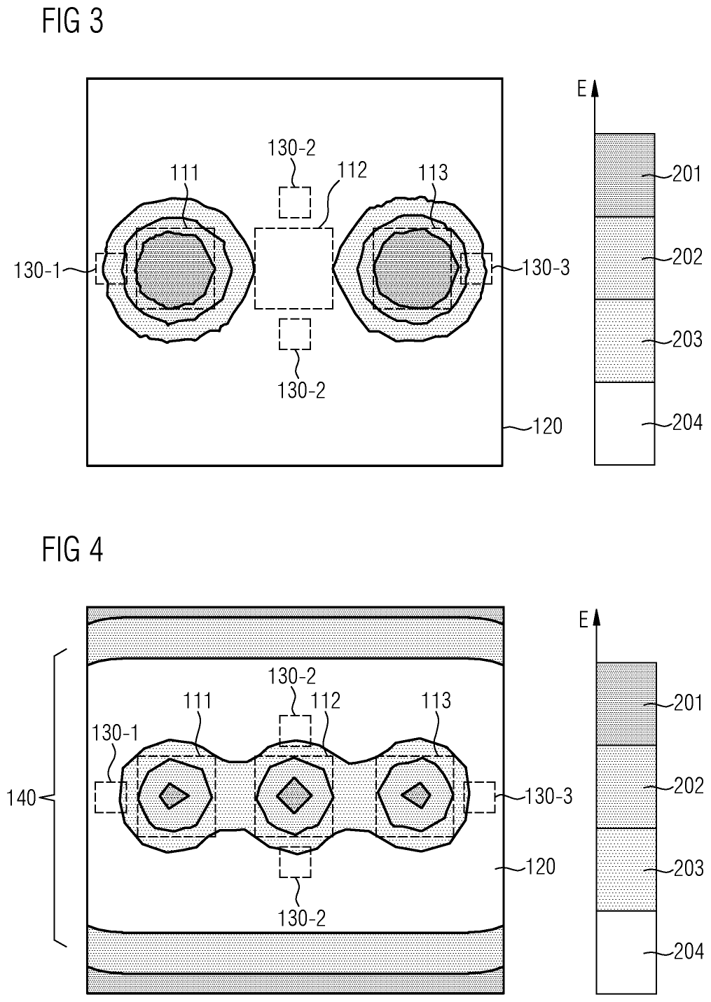

FIGS. 3 and 4 show an irradiance on the front-side surface of the driver chip for different operating conditions of the light-emitting component;

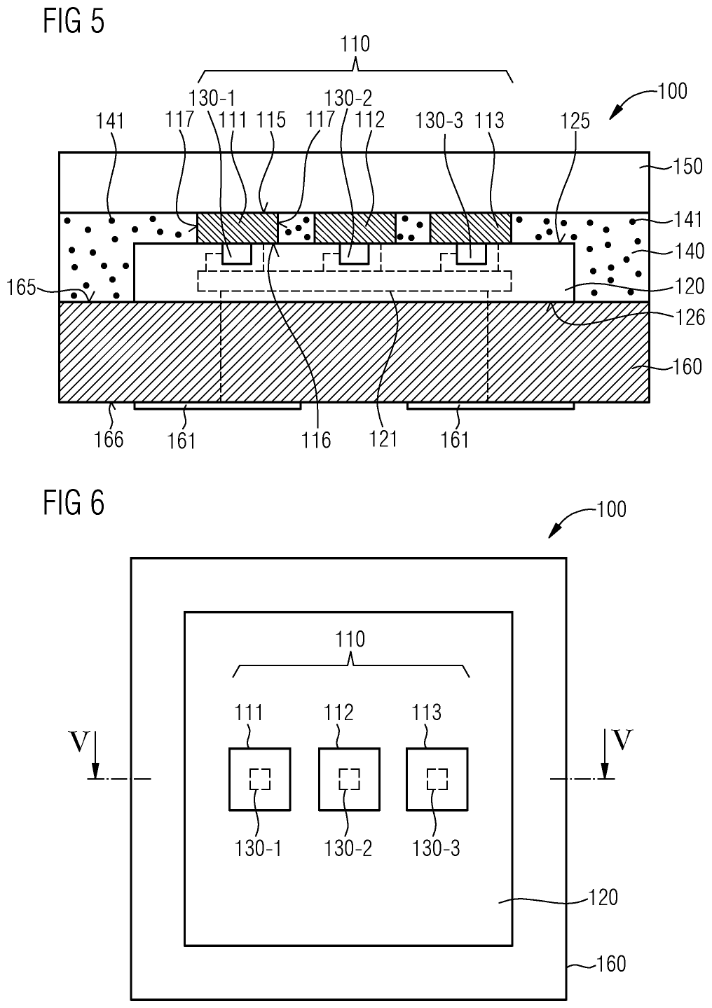

FIGS. 5 and 6 show a lateral sectional illustration and a plan view illustration of a further light-emitting component, in which the integrated photodiodes of the driver chip are located underneath the emitters;

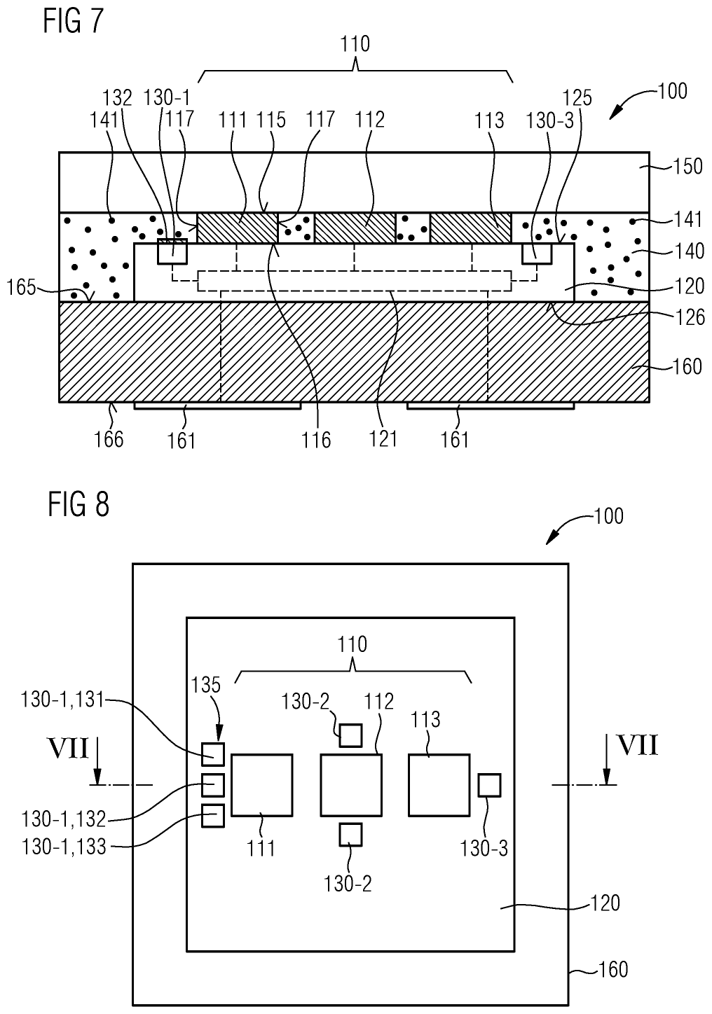

FIGS. 7 and 8 show a lateral sectional illustration and a plan view illustration of a further light-emitting component, in which the driver chip comprises upstream filters for a portion of the integrated photodiodes;

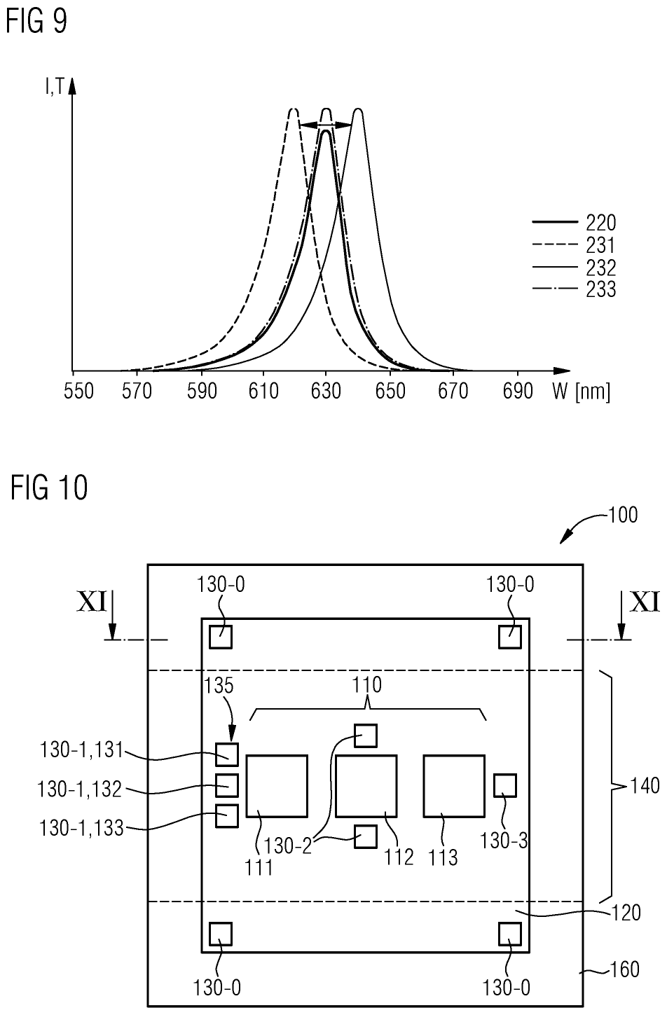

FIG. 9 shows a diagram illustrating an emission spectrum of an emitter and filter characteristics of filters; and

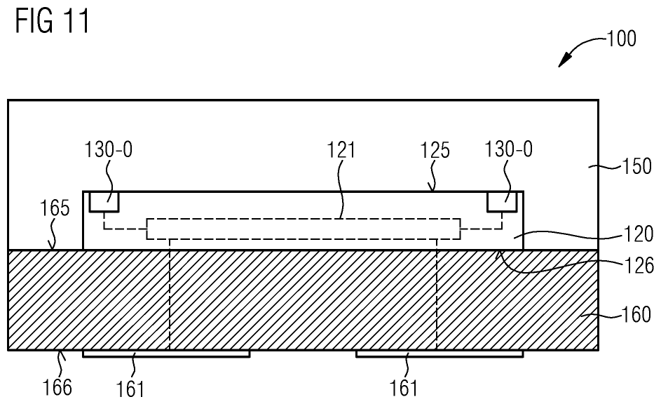

FIGS. 10 and 11 show a plan view illustration and a lateral sectional illustration of a further light-emitting component, in which the driver chip comprises additional photodiodes provided to detect an ambient light radiation.

Possible configurations of a light-emitting component 100 comprising a plurality of light-emitting semiconductor chips 111, 112, 113 and an electronic semiconductor chip 120 are described with reference to the following schematic figures. It is pointed out that the schematic figures may not be true to scale. Therefore, components, elements and structures shown in the figures may be illustrated with exaggerated size or size reduction in order to afford a better understanding. The figures show i.a. lateral cross-sectional illustrations and plan view illustrations of a light-emitting component 100. The plan view illustrations contain section lines that relate to section planes of the associated lateral cross-sectional illustrations.

FIG. 1 shows a lateral sectional view of a multicolor light-emitting component 100. A corresponding top view representation of the component 100 is depicted in FIG. 2. The light-emitting component 100 comprises an emitter group 110 of three light-emitting semiconductor chips 111, 112, 113 and an electronic semiconductor chip 120 for driving the light-emitting semiconductor chips 111, 112, 113, on which the light-emitting semiconductor chips 111, 112, 113 are arranged. The light-emitting semiconductor chips 111, 112, 113, which are referred to as emitters 111, 112, 113 in the following, are configured to generate differently colored light radiations. The light-emitting component 100 may be a RGB component such that the different light radiations include a red, a green and a blue light radiation. In this respect, the emitter 111 may produce the red light radiation, the emitter 112 may produce the green light radiation and the emitter 113 may produce the blue light radiation such that a red emitter 111, a green emitter 112 and a blue emitter 113 are present. The emitters 111, 112, 113 are arranged in the form of a row or fictitious line next to each other.

The electronic semiconductor chip 120 may also be referred to as IC (integrated circuit), driver IC or driver chip. For the following description, the designation driver chip 120 is applied. The in-package driver chip 120 is configured to individually drive the multiple emitters 111, 112, 113 to emit their respective light radiations, and thereby acts as a current source for each emitter 111, 112, 113 and therefore color channel. By appropriately or jointly driving the emitters 111, 112, 113, a total or mixed light radiation may be generated by the light-emitting component 100 with a predetermined color or chromaticity. The achievable color may be from a wide range of colors including white. Such characteristics may i.a. depend on the relative intensities of the individual light radiations generated by the emitters 111, 112, 113. Consequently, the chromaticity of the total light radiation may be set or changed by the driver chip 120 driving the individual emitters 111, 112, 113 accordingly to set or change the intensities of the generated light radiations.

The driving of the emitters 111, 112, 113 performed by the driver chip 120 may be based on a PWM (pulse width modulation) control scheme such that the emitters 111, 112, 113 are periodically operated for light emission. To this end, the driver chip 120 may periodically supply the emitters 111, 112, 113 with a nominal current. The ratio of durations of the on and off times and thus the duty cycle defines the perceivable average intensity and brightness of the respective light radiation. The driver chip 120 may therefore set or change the intensities of the light radiations generated by the emitters 111, 112, 113 by individually setting and changing the respective duty cycles.

The emitters 111, 112, 113 comprise a front side 115, a back side 116 opposite to the front side 115 and lateral sides 117 extending between and connecting the front and back side 115, 116, as illustrated in FIG. 1 with regard to the red emitter 111. The emitters 111, 112, 113 may be LED (light-emitting diode) chips. In this regard, the light-emitting component 100 may also be referred to as an LED package. The emitters 111, 112, 113 are furthermore volume-emitting semiconductor chips, also referred to as volume emitters, which are configured to emit the generated light radiation at least via the front side 115 and the lateral sides 117. This is illustrated in FIG. 1 with regard to the blue emitter 113 by means of arrows indicating the emission of a light radiation 200. Depending on the configuration, light emission may also take place via the back side 116, as it is applied e.g. with reference to the configuration illustrated in FIGS. 5 and 6. The emitters 111, 112, 113 may comprise a semiconductor layer sequence with an active zone for generation of the respective light radiation and a transmissive chip substrate such as a sapphire substrate (respectively not illustrated).

As shown in FIG. 1, the emitters 111, 112, 113 are mounted on a front side 125 of the driver chip 120 via their back sides 116. The emitters 111, 112, 113 are mechanically and electrically connected to the driver chip 120. In this regard, the emitters 111, 112, 113 and the driver chip 120 may comprise respective contacts that are connected to each other. The connection between the emitters 111, 112, 113 and the driver chip 120 and between their contacts may be realized by connection materials or structures such as a sol-der material, an adhesive or bond wires (respectively not illustrated).

Another constituent part of the light-emitting component 100 is a base carrier 160 on which the driver chip 120 is arranged. The base carrier 160 may be or may comprise a metallic lead frame, a ceramic carrier or a PCB (printed circuit board). The driver chip 120 is mounted on a front side 165 of the base carrier 160 via a back side 126 of the driver 120 opposite to its front side 125. The driver chip 120 is mechanically and electrically connected to the base carrier 160. In this regard, the driver chip 120 and the base carrier 160 may comprise respective contacts that are connected to each other. The connection may be realized by a connection material such as a solder material (respectively not illustrated). The base carrier 160 comprises further contacts 161 at a back side 166 opposite to its front side 165 via which the light-emitting component 100 may be electrically contacted and connected. In this way, by means of the back-side contacts 161, the light-emitting component 100 may be powered electrically and a communication with the light-emitting component 100 may be established.

As shown in FIGS. 1 and 2, the driver chip 120 comprises a plurality of integrated photodiodes 130 that are formed in a region of the front side 125 of the same. In the light-emitting component 100 depicted in FIGS. 1 and 2, the photodiodes 130 are furthermore located in regions laterally to the emitters 111, 112, 113. The photodiodes 130 are provided to detect the light radiations emitted by the emitters 111, 112, 113 of the emitter group 110 when operating the same in order to monitor these radiations. In this way, an in-package or integrated optical feedback system may be implemented so that the light-emitting component 100 may be controlled to emit a total light radiation with a predetermined characteristic or chromaticity. This will be described in more detail below. Each emitter 111, 112, 113 is associated with at least one photodiode 130 of the driver chip 120 in order to detect the light radiation generated by that respective emitter 111, 112, 113. The light-emitting component 100 is configured in such a way that the respective photodiodes 130 may be irradiated only or substantially only with the light radiations generated by the associated emitters 111, 112, 113.

In order to indicate the association of an integrated photodiode 130 with an emitter 111, 112, 113, the additional indices “−1”, “−2” and “−3” are applied in FIGS. 1 and 2 (and following figures) to indicate that a photodiode 130-1 is assigned to the red emitter 111, a photodiode 130-2 is assigned to the green emitter 112 and a photodiode 130-3 is assigned to the blue emitter 113. In the light-emitting component 100 depicted in FIGS. 1 and 2, the red and blue emitter 111, 113 are each associated with one photodiode 130-1 or 130-3, while the green emitter 112 is associated with two photodiodes 130-2 (see FIG. 2).

The photodiodes 130 of the driver chip 120 are formed identically and comprise diode structures such as a p-n-junction, which may be realized by inversely doped semiconductor layer regions of the driver chip 120 that are located in the region of its front side 125 (respectively not illustrated). The driver chip 120 may be based on the semiconductor material silicon, and therefore the photodiodes 130 may be silicon photodiodes. In case of irradiation of the photodiodes 130 with the light radiations generated by the emitters 111, 112, 113, the photodiodes 130 may produce measurement signals which reflect the respective radiations or their intensities and which may be processed by the driver chip 120.

Apart from the photodiodes 130, the driver chip 120 comprises circuit structures electrically connected to the emitters 111, 112, 113 and to the photodiodes 130 by means of which the aforementioned driving of the emitters 111, 112, 113 and processing of the photodiode signals provided by the photodiodes 130 upon being irradiated may be controlled and carried out. These circuit structures are illustrated schematically in FIG. 1 (and following figures) by dashed lines and in summarized form as IC logic 121. Electrical connections between the IC logic 121 and the emitters 111, 112, 113 and between the IC logic 121 and the photodiodes 130 are also indicated by dashed lines in FIG. 1 (and following figures). This likewise holds true for electrical connections between the driver chip 120 or its IC logic 121 and the back-side contacts 161 of the base carrier 160. The electrical connections indicated by the dashed lines comprise, apart from the aforementioned non-illustrated contacts of the emitters 111, 112, 113, the driver chip 120 and the base carrier 160 and the applied connection materials or structures, respective conductors or conductor structures of the driver chip 120 and of the base carrier 160.

As shown in FIG. 1, the light-emitting component 100 furthe comprises a reflective layer 140 which covers the driver chip 120 and its front side 125 in regions laterally to and between the emitters 111, 112, 113. In this way, the photodiodes 130 of the driver chip 120 are also covered by the reflective layer 140. The reflective layer 140 directly adjoins the front side 125 of the driver chip 120 and the lateral sides 117 of the emitters 111, 112, 113 and comprises such a thickness on the front side 125 of the driver chip 120 that the reflective layer 140 extends to the front sides 115 of the emitters 111, 112, 113, wherein the front sides 115 of the latter are not covered by the reflective layer 140. A surface of the reflective layer 140 is thereby flush with the front sides 115 of the emitters 111, 112, 113. The reflective layer 140 directly adjoins not only the driver chip 120 but also the base carrier 160 laterally to the driver chip 120 and therefore covers lateral sides of the driver chip 120 and the front side 165 of the base carrier 160. The reflective layer 140, which may be configured as a reflective casting compound and may comprise a white color, comprises a transmissive basic material such as silicone and reflective particles 141 embedded or distributed therein. The reflective particles 141 may be titanium dioxide (TiO2) particles.

The reflective layer 140 and its reflective particles 141 serve to reflect and scatter a light radiation, which includes the light radiations generated by the emitters 111, 112, 113 as well as an ambient light radiation. In this way, the photodiodes 130 assigned to the emitters 111, 112, 113 may be reliably irradiated by the light radiations generated by the respective emitters 111, 112, 113, and a blocking of the ambient light radiation may be achieved to prevent the ambient light radiation from interfering or severely interfering with the feedback system, as will be described in more detail below.

As shown in FIG. 1, the light-emitting component 100 furthermore comprises a transmissive cover layer 150 that is arranged on and covers the emitters 111, 112, 113 and the reflective layer 140. The cover layer 150 may be formed from e.g. clear silicone. By means of the cover layer 150, the emitters 111, 112, 113 may be protected from external influences. In operation of the light-emitting component 100, light emission may occur via the cover layer 150.

The emitters 111, 112, 113 of the light-emitting component 100 may experience unintended changes and deviations in the light radiations generated. This may be or include changes and deviations in the intensity of the light radiations, and may be due to influencing effects such as temperature fluctuations, variations in driving parameters such as emitter forward current, operating time and semiconductor degradation. As a result, there may be related changes and deviations in the total light radiation generated by the light-emitting component 100, e.g. in terms of color or chromaticity drifts. The layout and functionality of the light-emitting component 100, as will be described in the following, makes it possible to counteract or compensate for such changes and deviations so that the light-emitting component 100 may, despite the influencing effects, emit a total light radiation with a predetermined characteristic or chromaticity.

In operation of the light-emitting component 100, the light radiations emitted by the emitters 111, 112, 113 may be reliably detected and monitored by means of the integrated photodiodes 130 of the driver chip 120 assigned to the same. In this regard, the red light radiation generated by the red emitter 111 may be detected by the photodiode 130-1, the green light radiation generated by the green emitter 112 may be detected by the photodiodes 130-2, and the blue light radiation generated by the blue emitter 113 may be detected by the photodiode 130-3 (see FIG. 2). The photodiodes 130 upon being irradiated may accordingly produce measurement signals which may reproduce the respective light radiations or their intensities.

The driver chip 120 or its IC logic 121 are configured to control and adjust the driving of the emitters 111, 112, 113 in accordance with the measurement signals provided by the photodiodes 130. For this purpose, the photodiode signals are processed by the IC logic 121 which includes evaluation or analysis of the same. In case that the IC logic 121 determines from the evaluated photodiode signals that an unintended change or deviation in the light radiation generated by at least one emitter 111, 112, 113 occurs or is present, the driving of at least one emitter 111, 112, 113 is respectively adapted by the IC logic 121 to compensate for the change or deviation. In this context and with respect to the aforementioned PWM control scheme, the IC logic 121 may change the intensity of the light radiation generated by at least one emitter 111, 112, 113 by changing the corresponding duty cycle. In this way, the observed changes and deviations in the light radiations generated by the emitters 111, 112, 113 and thus related changes and deviations in a total light radiation generated by the light-emitting component 100 may be counteracted and compensated with the result that the component 100 may reliably emit a total light radiation with a predetermined characteristic or chromaticity. The light-emitting component 100 may therefore feature a high color point stability, which may apply over the full lifetime.

The aforementioned functionality is based on the fact that the integrated photodiodes 130 of the driver chip 120 may be irradiated only or substantially only with the light radiations generated by the associated emitters 111, 112, 113. This is achieved by the volume-emitting construction of the emitters 111, 112, 113, an appropriate location of the photodiodes 130 in regions laterally to the emitters 111, 112, 113, and the reflective layer 140 covering the front side 125 of the driver chip 120 in regions laterally and between the emitters 111, 112, 113. In this way, in operation of the light-emitting component 100, the emitters 111, 112, 113 may emit their respective light radiations i.a. via the lateral sides 117 such that the light radiations are coupled into the reflective layer 140 adjoining the lateral sides 117. As a result of this, and additionally due to the reflecting or scattering property of the reflective particles 141, it is possible that the reflective layer 140 is illuminated with the respective light radiations in regions close to and laterally enclosing the emitters 111, 112, 113. The light radiations may thereby propagate from the emitters 111, 112, 113 through the reflective layer 140 to the associated photodiodes 130. The location of the photodiodes 130 here is such that the photodiodes 130 are located as far as possible from the emitters 111, 112, 113 not associated with them or from the illuminated regions surrounding these emitters 111, 112, 113 with the result that an irradiation of the photodiodes 130 by these emitters 111, 112, 113 is prevented or substantially suppressed.

Moreover, the reflective layer 140 may reflect and scatter an ambient light radiation, and may therefore prevent or substantially suppress the ambient light radiation from reaching the integrated photodiodes 130 of the driver chip 120 associated with the emitters 111, 112, 113. This has the consequence that the ambient light radiation may not or may only be insignificantly noticeable in the measurement signals produced by the photodiodes 130, and thus that the photodiode signals may originate solely or substantially from the light radiations generated by the associated emitters 111, 112, 113. This is interrelated with a high signal-to-noise ratio. In this way, the in-package correction and compensation of unintended changes and deviations in the light radiations generated by the monitored emitters 111, 112, 113 may be established with a high accuracy and reliability.

In order to demonstrate the scattering and blocking effect of the reflective layer 140, FIGS. 3 and 4 illustrate, in the form of a plan view representation, a light irradiance E on the front side 125 of the driver chip 120 obtained by a simulation for different operating conditions of the light-emitting component 100. The locations of the emitters 111, 112, 113 of the emitter group 110 and of the photodiodes 130 is indicated by dashed lines. As shown by the additional diagram on the right side of FIGS. 3 and 4 respectively, different ranges 201, 202, 203, 204 of irradiance E are present. The irradiance range 201 represents relatively high values of irradiance E, the irradiance range 202 represents lower values of irradiance E compared to the range 201, the irradiance range 203 represents lower values of irradiance E compared to the range 202, and the irradiance range 204 represents lower values of irradiance E compared to the range 203, including an irradiance E of zero. It is pointed out that the irradiance ranges 201, 202, 203, 204 shown in FIGS. 3 and 4 and marked with the same reference symbols do not have to correspond to each other, and may indeed represent different values of irradiance E.

FIG. 3 shows a condition in which the red emitter 111 and the blue emitter 113 are powered on and emit the respective red and blue light radiation with full intensity, wherein the green emitter 112 is turned off. As a consequence, the irradiance E at the front side 125 of the driver chip 120 is relatively high at the emitters 111, 113 and decreases with increasing distance from them. In regions close to the emitters 111, 113 and enclosing them laterally, there is still a noticeable irradiance E. The photodiodes 130 located in these regions, i.e. the photodiode 130-1 assigned to the red emitter 111 and the photodiode 130-3 assigned to the blue emitter 113, are therefore exposed to a respective irradiation and may reliably and accurately detect the light radiations emitted by the corresponding emitters 111, 113. In contrast thereto, an irradiation of photodiodes 130 with light radiations generated by emitters 111, 112, 113 not assigned to the same does not occur or is suppressed. With respect to the condition indicated in FIG. 3, therefore, the photodiode 130-1 assigned to the red emitter 111 is not irradiated by the blue emitter 113, and the photodiode 130-3 assigned to the blue emitter is not irradiated by the red emitter 111, as can be derived from FIG. 3. In the same way, the photodiodes 130-2 assigned to the turned-off green emitter 112 are not irradiated by any of the emitters 111, 112, 113. Corresponding situations exist with other and from FIG. 3 differing on and off states of the emitters 111, 112, 113, i.e. that the photodiodes 130 may be irradiated only or noticeably only by their associated emitters 111, 112, 113.

FIG. 4 depicts another condition in which all emitters 111, 112, 113 are turned off and the light-emitting component 100 is subjected to ambient light in the form of direct solar irradiation. As a consequence, the irradiance E at the front side 125 of the driver chip 120 is relatively high at the emitters 111, 112, 113 or at a center of the same and decreases from there, wherein a relatively low irradiance E is present in regions close to the emitters 111, 112, 113 and enclosing them laterally. This is because the ambient light radiation may be coupled into the emitters 111, 112, 113 and, to some extent, emitted from them further into the reflective layer 140 via their lateral sides 117. In this way, the reflective layer 140 in regions laterally enclosing the emitters 111, 112, 113 may, to some degree, be illuminated with the ambient light radiation. This therefore also applies to the photodiodes 130. However, this irradiation contribution may be relatively weak and therefore negligible.

It becomes apparent from FIGS. 3 and 4 that, due to the reflective layer 140, the photodiodes 130 for the red, green and blue channel may be separated from each other with a high efficiency. Also, the influence of ambient light radiation may be effectively suppressed. For each emitter 111, 112, 113 operated at maximum intensity and in case of direct solar irradiation, a high signal-to-noise ratio, e.g. a ratio of 100:1 may be achieved.

FIG. 4 further indicates a possible configuration in which the front side 125 of the driver chip 120, apart from the spaces occupied by the emitters 111, 112, 113, is not fully covered by the reflective layer 140, but is left uncovered in two regions at the edge of the driver chip 120. Here, the approximate coverage of the driver chip 120 by the reflective layer 140 is indicated with a parenthesis. This layout has the effect that the irradiance E is relatively high at the uncovered regions. Such a structure is applied e.g. in the configuration depicted in FIGS. 10 and 11.

As indicated above, a communication may be established with the light-emitting component 100 via the back-side contacts 161 (see FIG. 1). This may include a communication between the light-emitting component 100 and an external main controller (not illustrated) that may be applied to control the operation of the light-emitting component 100. In this respect, the main controller may provide and communicate command signals to the light-emitting component 100 on the basis of which the driver chip 120 or its IC logic 121 may carry out the aforementioned driving of the emitters 111, 112, 113, taking into account the photodiode signals provided by the photodiodes 130 upon being irradiated. By means of the command signals, predetermined parameters of the total light radiation to be generated by the light-emitting component 100 may be specified, e.g. an intensity specification and a specification related to a color or chromaticity.

The light-emitting component 100 may be applied in a range of different technical fields. Examples include a direct view LED display or videowall, an LCD (liquid crystal display) backlight with dimming zones, a lighting device for automotive illumination or an indicator, a wallwasher and a stage-light. For applications of this kind, a plurality of light-emitting components 100 may be employed and operated in a combined manner, and may be controlled by an external main controller (respectively not illustrated). In this regard, the above-described photodiode-based optical feedback mechanism may be performed by each individual light-emitting component 100, which may therefore constitute an active chromaticity control at the level of the individual components 100 or a pixel-level chromaticity control.

A description is given below of further possible variants and configurations which may be considered in regard to a light-emitting component 100 described here. Corresponding features and details and also identical and identically acting components are not described in a detailed manner again below. For details in respect thereof, reference is instead made to the description above. Furthermore, aspects and details mentioned with regard to one configuration may also be applied with regard to another configuration and features of two or more configurations may be combined with one another.

A possible modification of the light-emitting component 100 depicted in FIGS. 1 and 2 is that the driver chip 120 comprises only one integrated photodiode 130 per emitter 111, 112, 113 of the monitored emitter group 110, and thus a total of three photodiodes 130. With reference to FIG. 2, in this sense, one of the photodiodes 130-2 associated with the green emitter 112 may be omitted (not illustrated).

Another possible modification is to provide the reflective layer 140 with a smaller layer thickness on the front side 125 of the driver chip 120, in deviation from FIG. 1, so that the emitters 111, 112, 113 may protrude from the reflective layer 140 (not illustrated).

FIGS. 5 and 6 show a lateral sectional illustration and a plan view illustration of a light-emitting component 100 according to a further configuration. In this configuration, the driver chip 120 again comprises one integrated photodiode 130 per emitter 111, 112, 113 of the monitored emitter group 110. These photodiodes 130 are furthermore located underneath the associated emitters 111, 112, 113 or the back sides 116 of the same. With regard to this layout, the emitters 111, 112, 113 are configured to emit the generated light radiations also via their back sides 116. In this way, the photodiodes 130 may each be irradiated directly via the back sides 116 of the associated emitters 111, 112, 113 and may thus detect the respective light radiations generated by them. Also in this way it may be reliably achieved that the photodiode signals produced by the photodiodes 130 upon being irradiated may originate solely or substantially from the light radiations generated by the associated emitters 111, 112, 113, thus enabling a high signal-to-noise ratio. This again provides a reliable and accurate compensation of changes and deviations in the light radiations generated by the emitters 111, 112, 113.

A possible modification of the light-emitting component 100 depicted in FIGS. 5 and 6 is to omit the reflective layer 140, thus enabling a cost saving. In this case, the driver chip 120, the emitters 111, 112, 113 and the base carrier 160 may be covered by the cover layer 150 (not illustrated).

As described above, the changes and deviations occurring in the light radiations generated by the emitters 111, 112, 113 due to influencing effects such as temperature variations and aging time may refer or may substantially refer to the intensity. This may apply to an LED chip comprising a semiconductor layer sequence based on InGaN. The green emitter 112 and blue emitter 113 may each be realized as such an InGaN-based LED chip. The changes due to influencing effects may additionally refer to the chromaticity of the particular emitter. This may apply to an LED chip comprising a semiconductor layer sequence based on InGaAlP. In this case, there may be a noticeable spectral dependency on temperature. The red emitter 111 may be realized as such an InGaAlP-based LED chip. With regard to this, the application of optical filters may be considered for a part of the photodiodes 130 of the driver chip 120 in order to also detect such changes in color or chromaticity.

For further illustration, FIGS. 7 and 8 show a lateral sectional illustration and a plan view illustration of a light-emitting component 100 according to a further configuration realized in this sense. The light-emitting component 100 depicted here differs from the configuration of FIGS. 1 and 2 in that the driver chip 120 comprises a photodiode group 135 of photodiodes 130-1 located next to each other in a region laterally to the red emitter 130-1, wherein the photodiodes 130-1 are assigned to the emitter 111 and provided to detect the light radiation generated by the emitter 111. In the illustrated implementation example, the photodiode group 135 comprises three photodiodes 130-1. The driver chip 120 furthermore comprises, for each photodiode 130-1, an upstream optical filter 131, 132, 133 with an individual filter characteristic that is different from the filter characteristics of the respective other filters 131, 132, 133. The filter characteristics are matched to the spectral behavior of the red emitter 111.

The three filters 131, 132, 133, each of which is associated with one of the photodiodes 130-1, are arranged on the photodiodes 130-1. The filters 131, 132, 133 are bandpass or narrow bandpass filters, and are configured as filter layers comprising e.g. a dielectric material. This layout is indicated in FIG. 7 with regard to the filter 132 provided for one of the photodiodes 130-1, i.e. the photodiode 130-1 that is located in the middle of the photodiode group 135 with reference to FIG. 8. The layout shown in FIG. 7 applies in a corresponding manner to the other filters 131, 133 which are each provided for one of the other photodiodes 130-1 located laterally of the middle photodiode 130-1.

Similar to the light-emitting component 100 depicted in FIGS. 1 and 2, in operation of the light-emitting component 100 set up according to FIGS. 7 and 8, the filtered photodiodes 130-1 may be irradiated only or substantially only with the light radiation generated by the red emitter 111. In this respect, the reflective layer 140 may be illuminated with the red light radiation in a region laterally enclosing the emitter 111 (see FIG. 3), and the red light radiation may thus propagate from the emitter 111 through the reflective layer 140 and additionally through the filters 131, 132, 133 to the photodiodes 130-1. The filters 131, 132, 133 thereby cause a filtering of the red light radiation. The measurement signals then produced by the photodiodes 130-1 upon being irradiated with the respective filtered light radiation may be processed or evaluated by the driver chip 120 or its IC logic 121. The same applies to the photodiode signals provided by the other photodiodes 130, i.e. the photodiodes 130-2, 130-3. On the basis of this, the IC logic 121 may control and adjust the driving of the emitters 111, 112, 113.

In the light-emitting component 100 illustrated in FIGS. 7 and 8, the red emitter 111 may experience, in addition to changes in intensity, changes in color point or chromaticity due to e.g. temperature variations with the result that related changes in the total light radiation generated by the light-emitting component 100 may occur. Such changes may be reliably detected by means of the measurement signals produced by the photodiodes 130-1 of the triple-filtered photodiode array 135, so that these changes may be counteracted and compensated by the IC logic 121 of the driver chip 120 correspondingly driving or adapting the driving of at least one emitter 111, 112, 113 of the monitored emitter group 110. The reason for this is that a change in color point or chromaticity of the red light radiation is accompanied by a spectral shift of the intensity distribution, which may be reproduced by the measurement signals or changes in the measurement signals provided by the photodiodes 130-1. As indicated above, the applied filters 131, 132, 132 are matched to the spectral behavior of the red emitter 111 to this end so that the photodiode signals may be subject to such changes.

In order to illustrate this condition, FIG. 9 shows a diagram with a possible emission spectrum 220 of the red emitter 111 and different possible filter characteristics 231, 232, 233 which may be present in relation to the filters 131, 132, 133 of the light-emitting component 100 depicted in FIGS. 7 and 8. The emission spectrum 220 illustrates the course of the intensity I and the filter characteristics 231, 232, 233 illustrate the course of the transmittance T, in each case in arbitrary units and depending on the wavelength W given in nanometers. By means of the additional double arrow, possible drifts in the emission spectrum 220, which is equivalent to changes in the color point or chromaticity, are indicated. FIG. 9 demonstrates that, depending on the spectral position or shape of the emitted red light radiation, different filtering of the light radiation by the filters 131, 132, 133 may take place which may also make the photodiodes 130-1 assigned to the red emitter 111 produce different photodiode signals. Consequently, on the basis of these photodiode signals, such effects may be detected and therefore compensated.

As described above, there is a possibility that the photodiodes 130 of the driver chip 120 associated with the emitters 111, 112, 113 of the monitored emitter group 110 may be irradiated to some degree with ambient light radiation with the result that the photodiode signals may be influenced by this to some extent. This effect may be addressed by configuring the light-emitting component 100 in such a way that at least one integrated photodiode 130 of the driver chip 120 is provided to detect the ambient light radiation.

For further illustration, FIGS. 10 and 11 show a plan view illustration and a lateral sectional illustration of a light-emitting component 100 according to a further configuration realized in this sense. The light-emitting component 100 depicted here represents a modification of the component 100 of FIGS. 7 and 8 in that the driver chip 120 comprises additional photodiodes 130 that are not associated with the emitters 111, 112, 113 and therefore not intended for detecting the light radiations generated by them, but instead are intended for detecting the ambient light radiation. These photodiodes 130 are identified with the reference symbol 130-0 to distinguish them from the other photodiodes 130-1, 130-2, 130-3. In the illustrated implementation example, four photodiodes 130-0 are provided, and the photodiodes 130-0 are located at a distance from the emitters 111, 112, 113 and at the corners of the driver chip 120. The photodiodes 130-0 are also formed in a region of the front side 125 of the driver chip 120 and are configured in the same way as the other photodiodes 130-1, 130-2, 130-3 (except for the filters 131, 132, 133 provided on the photodiodes 130-1). It is pointed out that the cross-sectional view of FIG. 7, with respect to the region where the emitters 111, 112, 113 are present, may be applied correspondingly to the light-emitting component 100 shown in FIGS. 10 and 11.

In order to achieve that the photodiodes 130-0 may by irradiated unhindered with the ambient light radiation, the photodiodes 130-0 are not covered by the reflective layer 140. To this end, the reflective layer 140 is formed in such a way that edge regions of the driver chip 120 in which the photodiodes 130-0 are present are free of the reflective layer 140. As illustrated in FIG. 10 by means of dashed lines, the reflective layer 140 for this purpose may cover the driver chip 120 and the base carrier 160 in a region in which the emitters 111, 112, 113 and their associated photodiodes 130-1, 130-2, 130-3 are present. Moreover, in two regions laterally thereof, the reflective layer 140 may be excluded so that the driver chip 120 and the base carrier 160 in these regions are not covered with the reflective layer 140 but with the cover layer 150 instead (see also FIG. 11).

In operation of the light-emitting component 100 configured according to FIGS. 10 and 11, the photodiodes 130-0 may be irradiated with the ambient light radiation and produce respective measurement signals which may be processed or evaluated by the driver chip 120 or its IC logic 121. In this way, the influence of the ambient light radiation may be determined and factored out when evaluating the measurement signals produced by the other photodiodes 130-1, 130-2, 130-3. Thus, an improved signal-to-noise ratio may be achieved.

The aforementioned approach of using photodiodes 130 to detect the ambient light radiation may be applied in a corresponding manner with respect to the light-emitting components 100 explained previously in that the driver chip 120 is provided with at least one additional photodiode 130 and the region in which that photodiode 130 is present is provided to be free of the reflective layer 140 (not illustrated).

Besides the embodiments described above and depicted in the figures, further embodiments are conceivable which may comprise further modifications and/or combinations of features.

As described above, the driving of emitters 111, 112, 113 carried out by a driver chip 120 may be based on a PWM control scheme. It is further conceivable, if applicable, to additionally or alternatively apply a current control scheme. In this regard, the applied driver chip 120 or its IC logic 121 may set and change a nominal current supplied to the emitters 111, 112, 113. In this way, the color point of the light radiations generated by the emitters 111, 112, 113 may be set and changed.

Moreover, deviating from above mentioned materials, other materials may be utilized for components of a light-emitting component 100.

Further modifications may include e.g. configuring a light-emitting device 100 with other numbers and/or arrangements of emitters and/or photodiodes 130. As an example, instead of arranging emitters 111, 112, 113 in the form of a row next to each other as shown in the plan view illustrations of FIGS. 2, 6, 8, 10, 11, a triangular arrangement may be considered.

It is also possible to apply emitters configured to produce a light radiation of a color other than those mentioned. This may include a white color. In this regard, e.g. an RGBW component may be realized which comprises, in addition to a red, green and blue emitter, a white emitter or white-emitting semiconductor chip configured to generate a white light radiation. Such an emitter may comprise a phosphor layer for radiation conversion.

Furthermore, configurations are conceivable in which only a portion of the emitters is monitored by photodiodes 130 of a driver chip 120 and at least one emitter is not. In this case, the emitters to which photodiodes 130 to detect the generated light radiation are assigned may be considered to be part of the monitored emitter group 110, and the unmonitored emitter, on the other hand, not.

With respect to employing an external main controller to control the operation of a light-emitting component 100, a furthe modification is to configure a driver chip 120 of the component 100 in such a way that the driver chip 120, instead of evaluating photodiode signals produced by integrated photodiodes 130, communicates such signals, if applicable in processed form such as in the form of digital signals, to the main controller. It is conceivable that these signals are evaluated by the main controller and that the main controller provides respective command signals on this basis.

Although the invention has been more specifically illustrated and described in detail by means of preferred exemplary embodiments, nevertheless the invention is not restricted by the examples disclosed and other variations may be derived therefrom by a person skilled in the art, without departing from the scope of protection of the invention.

### REFERENCE SYMBOLS

100 light-emitting component
110 emitter group
111 emitter
112 emitter
113 emitter
115 front side
116 back side
117 lateral side
120 driver chip
121 IC logic
125 front side
126 back side
130 photodiode
131 filter
132 filter
133 filter
135 photodiode group
140 reflective layer
141 reflective particle
150 cover layer
160 base carrier
161 contact
200 light radiation
201 irradiance range
202 irradiance range
203 irradiance range
204 irradiance range
220 emission spectrum
231 filter characteristic
232 filter characteristic
233 filter characteristic
E irradiance
I intensity
T transmittance
W wavelength

1. A light-emitting component comprising an emitter group of light-emitting semiconductor chips configured to generate different light radiations and an electronic semiconductor chip for driving the light-emitting semiconductor chips,
wherein the light-emitting semiconductor chips are arranged on the electronic semiconductor chip,
wherein the electronic semiconductor chip comprises a plurality of integrated photodiodes,
wherein each light-emitting semiconductor chip of the emitter group is associated with at least one photodiode of the electronic semiconductor chip in order to detect the light radiation generated by the respective light-emitting semiconductor chip, and
further comprising a reflective layer comprising reflective particles arranged on the electronic semiconductor chip in regions laterally to and between the light-emitting semiconductor chips.

2. The light-emitting component according to claim 1,
wherein the electronic semiconductor chip is configured to drive the light-emitting semiconductor chips in response to the light radiation detected by the photodiodes associated with the light-emitting semiconductor chips.

3. The light-emitting component according to claim 1,
wherein the light-emitting semiconductor chips are volume-emitting semiconductor chips configured to emit the generated light radiation via a front side and lateral sides of the semiconductor chips.

4. The light-emitting component according to claim 1,
wherein the photodiodes-associated with the light-emitting semiconductor chips are located in regions laterally to the respective light-emitting semiconductor chips such that these photodiodes may be irradiated with the light radiation generated by the respective light-emitting semiconductor chips via the reflective layer.

5. The light-emitting component according to claim 1,
wherein the photodiodes associated with the light-emitting semiconductor chips are located underneath the respective light-emitting semiconductor chips such that these photodiodes may be irradiated with the light radiation generated by the respective light-emitting semiconductor chips via a back side of the respective light-emitting semiconductor chips.

6. The light-emitting component according to claim 1,
wherein the emitter group comprises a red-emitting semiconductor chip configured to generate a red light radiation, a green-emitting semiconductor chip configured to generate a green light radiation and a blue-emitting semiconductor chip configured to generate a blue light radiation.

7. The light-emitting component according to claim 1,
wherein at least one of the light-emitting semiconductor chips is associated with a photodiode group of photodiodes of the electronic semiconductor chip in order to detect the light radiation generated by that light-emitting semiconductor chip,
and wherein the electronic semiconductor chip comprises, for each of the photodiodes of the photodiode group, an upstream filter with an individual filter characteristic that is different from the filter characteristics of the respective other filters.

8. The light-emitting component according claim 7,
wherein the light-emitting semiconductor chip associated with the photodiode group is a red-emitting semiconductor chip configured to generate a red light radiation.

9. The light-emitting component according to claim 7,
wherein the upstream filters are realized in the form of filter layers that are arranged on the photodiodes of the photodiode group.

10. The light-emitting component according to claim 1,
wherein the electronic semiconductor chip comprises at least one photodiode provided to detect an ambient light radiation.

11. The light-emitting component according to claim 10,
wherein the at least one photodiode-provided to detect the ambient light radiation is not covered by the reflective layer.

12. The light-emitting component according to claim 1,
wherein the electronic semiconductor chip is configured to process measurement signals produced by the photodiodes that may be generated by the photodiodes upon being irradiated by the associated light-emitting semiconductor chips.

13. The light-emitting component according to claim 1,
wherein the light-emitting semiconductor chips are arranged on a front side of the electronic semiconductor chip, and wherein the photodiodes of the electronic semiconductor chip are formed in a region of the front side of the electronic semiconductor chip.

14. The light-emitting component according to claim 1,
further comprising at least one of the following:
a base carrier on which the electronic semiconductor chip is arranged, and
a transmissive cover layer.

15. The light-emitting component according to claim 4,
wherein the photodiodes are located in such a way that an irradiation of the photodiodes with light radiations generated by light-emitting semiconductor chips that are not assigned to these photodiodes is prevented or substantially suppressed.

16. The light-emitting component according to claim 7,
wherein the filters are matched to a spectral behavior of the light-emitting semiconductor chip associated with the photodiode group.

17. A light-emitting component comprising an emitter group of light-emitting semiconductor chips configured to generate different light radiations and an electronic semiconductor chip for driving the light-emitting semiconductor chips,
wherein the light-emitting semiconductor chips are arranged on the electronic semiconductor chip,
wherein the electronic semiconductor chip comprises a plurality of integrated photodiodes,
wherein each light-emitting semiconductor chip of the emitter group is associated with at least one photodiode of the electronic semiconductor chip in order to detect the light radiation generated by the respective light-emitting semiconductor chip,
wherein the light-emitting component further comprises a reflective layer comprising reflective particles arranged on the electronic semiconductor chip in regions laterally to and between the light-emitting semiconductor chips,
wherein the photodiodes associated with the light-emitting semiconductor chips are located in regions laterally to the respective light-emitting semiconductor chips such that these photodiodes may be irradiated with the light radiation generated by the respective light-emitting semiconductor chips via the reflective layer, and
wherein the photodiodes are located in such a way that an irradiation of the photodiodes with light radiations generated by light-emitting semiconductor chips that are not assigned to these photodiodes is prevented or substantially suppressed.

18. A light-emitting component comprising an emitter group of light-emitting semiconductor chips configured to generate different light radiations and an electronic semiconductor chip for driving the light-emitting semiconductor chips,
wherein the light-emitting semiconductor chips are arranged on the electronic semiconductor chip,
wherein the electronic semiconductor chip comprises a plurality of integrated photodiodes,
wherein each light-emitting semiconductor chip of the emitter group is associated with at least one photodiode of the electronic semiconductor chip in order to detect the light radiation generated by the respective light-emitting semiconductor chip,
wherein at least one of the light-emitting semiconductor chips is associated with a photodiode group of photodiodes of the electronic semiconductor chip in order to detect the light radiation generated by that light-emitting semiconductor chip, and
wherein the electronic semiconductor chip comprises, for each of the photodiodes of the photodiode group, an upstream filter with an individual filter characteristic that is different from the filter characteristics of the respective other filters.
